(19) United States
(12) Patent Application Publication
(10) Pub. No.: US 2002/0000618 A1
(43) Pub. Date: Jan. 3, 2002

(54) Semiconductor device and method for fabricating the same

(75) Inventors: Masanobu Saito, Chiba-Shi (JP); Akira Umezawa, Yokohama-Shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Kawasaki-shi (JP)

(21) Appl. No.: 09/843,860

(22) Filed: Apr. 30, 2001

(30) Foreign Application Priority Data
May 1, 2000 (JP) 2000-132684

(51) Int. Cl. H01L 31/119; H01L 31/113; H01L 29/94

(52) U.S. Cl. 257/368

(57) ABSTRACT

A semiconductor device and a method for fabricating the same according to the present invention are characterized by the shape of a gate electrode, the shape or the range of a diffusion layer forming ion implantation region, or the peripheral shape of an element region, or, characterized in that an insulating film for coating a part of an element region formed before ion implantation.

### CROSS REFERENCE TO RELATED APPLICATIONS

The subject application is related to subject matter disclosed in Japanese Patent Application No. 2000-132684 filed on May 1, 2000 in Japan to which the subject application claims priority under Paris Convention and which is incorporated herein by reference.

### BACKGROUND OF THE INVENTION

1. Field of the Invention

The present invention relates generally to a semiconductor device and a method for fabricating the same. More specifically, the invention relates to a MOS transistor having a high junction withstand voltage and a method for fabricating the same.

2. Related Background Art

If a high voltage is applied to a drain diffusion layer in a MOS transistor, the withstand voltage of the whole diffusion layer depends on the withstand voltage of the boundary portion between the diffusion layer and an element isolating region since the withstand voltage of the boundary portion between the diffusion layer and the element isolating region is lower than that of the bottom of the diffusion layer.

In this respect, the constructions of two kinds of conventional MOS transistors will be described below.

FIGS. 1A and 1B are plan and sectional views of a first conventional MOS transistor. FIG. 1B is a sectional view taken along line X-X′ of FIG. 1A.

The first conventional MOS transistor comprises: element isolating regions 2, formed in the surface portion of a first conductive type semiconductor substrate 4 by the LOCOS method, for separating an element region 10; a gate electrode 1 which is formed so as to cross a central portion above the semiconductor substrate 4 in the element region 10 separated by the element isolating region 2; and second conductive type diffusion layer regions 3 which are formed in the surface portion of the semiconductor substrate 4 in regions included in one and the other of the element region 10 divided by the gate electrode 1 into substantially halves.

In the first conventional MOS transistor, in order to realize a high junction withstand voltage, a diffusion layer forming ion implantation region 11, which is used for forming the second conductive type diffusion layer region 3, is smaller than the element region 10 and is completely included in the element region 10. That is, by avoiding a high-density ion implantation into the boundary portion between the element region 10 and the element isolating region 2, the lowering of the junction withstand voltage at the boundary portion is prevented.

FIGS. 2A and 2B are plan and sectional views of a second conventional MOS transistor. FIG. 2B is a sectional view taken along line X-X′ of FIG. 2A.

The second conventional MOS transistor comprises: a shallow trench isolation (STI) region 7, formed so as to extend from the surface portion of a first conductive type semiconductor substrate 4 to a predetermined depth, for separating an element region 10; a gate electrode 1 which is formed so as to have a central crossing portion crossing a central portion above the semiconductor substrate 4 in the element region 10 separated by the STI region 7, a frame portion covering the boundary portion between the STI region 7 and the element region 10, and two openings surrounded by the central crossing portion and the frame portion; and second conductive type diffusion layer regions 3 which are formed in the surface portion of the semiconductor substrate 4 in the two opening regions of the gate electrode 1, respectively.

In the second conventional MOS transistor, in order to realize a high junction withstand voltage, the gate electrode 1 is formed so as to have the frame portion covering the boundary portion between the STI region 7 and the element region 10. That is, by covering the whole boundary portion between the STI region 7 and the element region 10, a high-density ion implantation into the boundary portion is avoided, so that the lowering of the junction withstand voltage at the boundary portion is prevented.

However, in the above described first and second conventional MOS transistors, there are the following problems.

In the first conventional MOS transistor, if the doping of impurities into the gate electrode 1 of a polycrystalline silicon is intended to be carried out simultaneously with the ion implantation for forming the source/drain diffusion layers 3, there are problem in that it is not possible to implant ions into a portion of the gate electrode above the boundary portion between the element region 10 and the element isolating region 2, so that the parasitic resistance from a contact portion 1C of the gate electrode 1, which is arranged outside of the element region 10 for connecting the gate electrode 1 to another wiring layer, to a portion of the gate electrode above a channel region.

In addition, if a salicide (self-aligned silicide) process is introduced, a diffusion layer forming impurity introducing region on the element region 10 is electrically connected to a non-introducing region thereon via silicide, so that there is a problem in that leak occurs between the diffusion layer and the substrate.

On the other hand, in a MOS transistor having a similar construction as that of the second conventional MOS transistor, there is particularly no problem when an element isolating region is formed by the LOCOS method. However, if the element isolating region is the STI region 7 formed by the STI method as the second conventional MOS transistor, there is a problem in that, in a right-angle corner portion of the boundary portion between the element region 10 and the STI region 7, a short circuit is easily established between the gate electrode covering the boundary portion and the substrate.

### SUMMARY OF THE INVENTION

It is therefore an object of the present invention to eliminate the aforementioned problems and to provide a semiconductor device having a high junction withstand voltage by preventing the lowering of a junction withstand voltage in the boundary portion of an element region and an element isolating region, and a method for fabricating the same.

According to a first construction of a semiconductor device of the present invention, there is provided with a semiconductor device comprising: an element isolating region, formed in the surface portion of a first conductive type semiconductor substrate, for separating an element region; a gate electrode crossing a central portion above said semiconductor substrate in said element region separated by said element isolating region, said gate electrode having a contact portion for connecting to another wiring layer, which is arranged at one end outside of said element region, and said gate electrode having a shape which covers a boundary portion between said element region, which is arranged between said contact portion and an interior of said element region, and said element isolating region, over a length exceeding a gate length in the central portion of said element region; an ion implantation region for forming a diffusion layer, whose most part is included in said element region, and one part protrudes from said most part to include said contact portion of said gate electrode, said ion implantation region being arranged to avoid said boundary portion; and second conductive type diffusion layer regions which are each formed in the surface portion of said semiconductor substrate in regions included in one and the other of said element region divided by said gate electrode into substantially halves.

With this construction, the impurity doping into a gate electrode can be carried out simultaneously with the ion implantation for forming source and drain diffusion layers while suppressing the increase of a parasitic resistance from the contact portion of the gate electrode to a portion above a channel region, and it is possible to prevent the lowering of a junction withstand voltage at the boundary portion between an element region and an element isolating region by avoiding a high-density ion implantation into the boundary portion.

According to a second construction of a semiconductor device of the present invention, there is provided with a semiconductor device comprising: an element isolating region, formed in the surface portion of a first conductive type semiconductor substrate, for separating an element region; a gate electrode crossing a central portion above said semiconductor substrate in said element region separated by said element isolating region, said gate electrode having a contact portion for connecting to another wiring layer, which is arranged at one end outside of said element region, and said gate electrode having a shape which covers a boundary portion between said element region, which is arranged between said contact portion and an interior of said element region, and said element isolating region, over a length exceeding a gate length in the central portion of said element region; an insulating film which covers the boundary portion between said element region and said element isolating region as a frame shape except for a portion which said gate electrode is formed; an ion implantation region for forming a diffusion layer, which is arranged in a range including all of said gate electrode and said insulating film; second conductive type diffusion layer regions each formed in the surface portion of said semiconductor substrate in regions included in one and the other of said element region which is divided by said gate electrode into substantially halves and which is surrounded by said insulating layer; and a salicide layer which is formed on the top face of said gate electrode and in the surface portion of said second conductive type diffusion layer regions.

With this construction, it is possible to realize a high junction withstand voltage even if a salicide process is introduced.

According to a third construction of a semiconductor device of the present invention, there is provided with a semiconductor device comprising: an STI (shallow trench isolation) region, formed so as to extend from the surface portion of a first conductive type semiconductor substrate to a predetermined depth, for separating an element region; a gate electrode which is formed to have a central crossing portion crossing a central portion above said semiconductor substrate in said element region separated by said STI region, a frame portion covering a pair of two facing sides of the boundary portion between said STI region and said element region and a inside portion of the other two sides of said boundary portion except for the corner portions of said boundary portion, and two openings surrounded by said central crossing portion and said frame portion; an ion implantation region for forming a diffusion layer, wherein a pair of facing boundary lines are arranged on said frame portion of said gate electrode covering the inside portion of the other two sides of the boundary portion between said STI region and said element region, and wherein the other pair of facing boundary lines are arranged outside of said gate electrode and said element region; and second conductive type diffusion layer regions each formed in the surface portion of said semiconductor substrate in said two opening regions of said gate electrode, respectively.

With this construction, even if an element isolating region is an STI region formed by the STI method, it is possible to avoid establishing a shirt circuit between a gate electrode and a substrate particularly in the corner portions of the boundary portion between an element region and the STI region, and a diffusion layer region is not electrically connected to the boundary portion, so that it is possible to realize a high junction withstand voltage.

According to a fourth construction of a semiconductor device of the present invention, there is provided with a semiconductor device comprising: an STI region, formed so as to extend from the surface portion of a first conductive type semiconductor substrate to a predetermined depth, for separating an element region; a gate electrode which is formed to have a central crossing portion crossing a central portion above said semiconductor substrate in said element region separated by said STI region, a frame portion covering a pair of two facing sides of the boundary portion between said STI region and said element region and a inside portion of the other two sides of said boundary portion except for the corner portions of said boundary portion, and two openings surrounded by said central crossing portion and said frame portion; an insulating film formed so as to cover said element region outside of said frame portion of said gate electrode and said boundary portion; an ion implantation region for forming a diffusion layer, formed in a range including all of said gate electrode and said insulating film; second conductive type diffusion layer regions each formed in the surface portion of said semiconductor substrate in said two opening regions of said gate electrode; and a salicide layer formed on the exposed top face of said gate electrode and in the surface portion of said second conductive type diffusion layer region.

With this construction, even if an element isolating region is an STI region formed by the STI method, it is possible to avoid establishing a shirt circuit between a gate electrode and a substrate particularly in the corner portions of the boundary portion between an element region and the STI region, and a diffusion layer region is not electrically connected to the boundary portion, so that it is possible to realize a high junction withstand voltage.

According to a fifth construction of a semiconductor device of the present invention, there is provided with a semiconductor device comprising: an STI region, formed so as to extend from the surface portion of a first conductive type semiconductor substrate to a predetermined depth, for separating a substantially rectangular element region, each corner portion of which has an arc shape or a plurality of corners of an acute angle; a gate electrode which is formed to have a central crossing portion crossing a central portion above said semiconductor substrate in said element region separated by said STI region, a frame portion covering the boundary portion between said STI region and said element region, and two openings surrounded by said central crossing portion and said frame portion; an ion implantation region for forming diffusion layer, formed in a range including all of said gate electrode; and second conductive type diffusion layer regions formed in the surface portion of said semiconductor substrate in said two opening regions of said gate electrode, respectively.

With this construction, since a right-angled or acute-angled portion is removed from the peripheral shape of an element region, it is possible to prevent a short circuit from being established between a gate electrode, which covers a boundary portion between the element region and an STI region, and a substrate in the corner portions of the boundary portion, so that it is possible to realize a high junction withstand voltage.

A method for fabricating each of the above described constructions of a semiconductor device according to the present invention fabricates each of the above described constructions of a semiconductor device according to the present invention by a usual process in accordance with each of the above described constructions of a semiconductor device according to the present invention, so that it is possible to obtain the advantages in each of the above described constructions.

Furthermore, if the insulating film in the method for fabricating the second construction of a semiconductor device according to the present invention is formed by utilizing a gate-side wall forming insulating film for a salicide process, the process can be simplified, and the number of steps can be substantially equal to that in the conventional methods.

In the method for fabricating the third construction of a semiconductor device according to the present invention, the impurity doping into the gate electrode and diffusion layer region can be carried out at the same step.

In the method for fabricating the fourth construction of a semiconductor device according to the present invention, the impurity doping into the gate electrode and diffusion layer region can be carried out at the same step. If the insulating film is formed by utilizing a gate-side wall forming insulating film for a salicide process, the process can be simplified, and the number of steps can be substantially equal to that in the conventional methods.

### BRIEF DESCRIPTION OF THE DRAWINGS

The present invention will be understood more fully from the detailed description given herebelow and from the accompanying drawings of the preferred embodiments of the invention. However, the drawings are not intended to imply limitation of the invention to a specific embodiment, but are for explanation and understanding only.

In the drawings:

FIGS. 1A and 1B are plan and sectional views showing the construction of a first conventional MOS transistor;

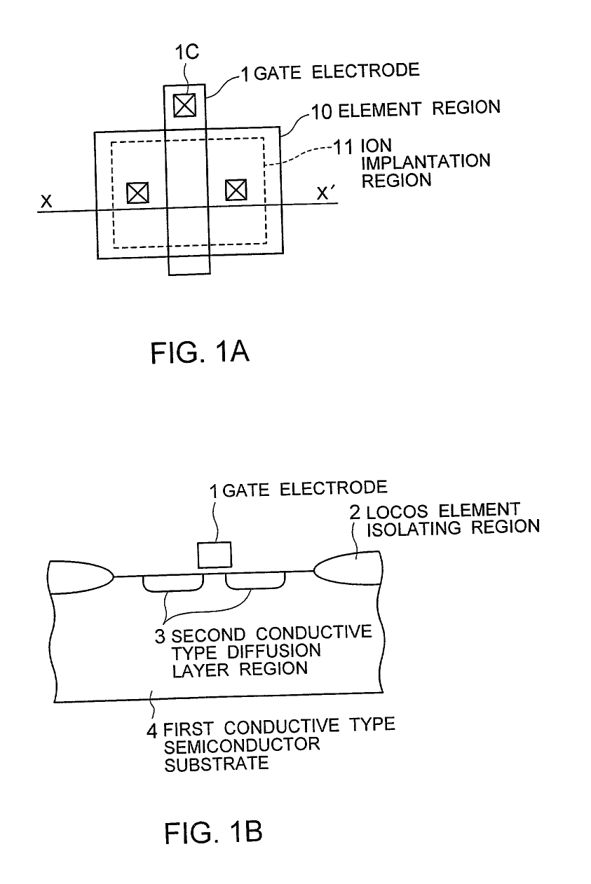

FIGS. 2A and 2B are plan and sectional views showing the construction of a second conventional MOS transistor;

FIGS. 3A and 3B are plan and sectional views showing the construction of the first preferred embodiment of a semiconductor device according to the present invention;

FIGS. 4A and 4B are plan and sectional views showing the construction of the second preferred embodiment of a semiconductor device according to the present invention;

FIGS. 5A and 5B are plan and sectional views showing the construction of the third preferred embodiment of a semiconductor device according to the present invention;

FIGS. 6A and 6B are plan and sectional views showing the construction of the fourth preferred embodiment of a semiconductor device according to the present invention;

FIGS. 7A, 7B, 7C and 7D are sectional views showing principal steps of a method for fabricating the fourth preferred embodiment of a semiconductor device according to the present invention; and

FIGS. 8A and 8B are plan and sectional views showing the construction of the fifth preferred embodiment of a semiconductor device according to the present invention.

### DESCRIPTION OF THE PREFERRED EMBODIMENTS

A semiconductor device and a method for fabricating the same according to the present invention is characterized by a construction capable of avoiding forming a diffusion layer in the boundary portion between an element region and an element isolating region while eliminating the aforementioned problems in order to improve the junction withstand voltage of a drain diffusion layer.

When the element isolating region has the STI structure, if a gate electrode is arranged on the corner portion of the boundary portion between the element region and the element isolating region, a short circuit is easily established between the gate electrode and a substrate. Therefore, a semiconductor device and a method for fabricating the same according the present invention is characterized by a construction wherein the gate electrode is formed in a region other than the corner portion of the boundary portion and which is capable of avoiding the formation of a diffusion layer in the element region including the corner portion of the boundary portion which is not covered with the gate electrode.

When a method for fabricating a semiconductor device according to the present invention includes a salicide step, the method is characterized in that an element region including the corner portion of the boundary portion, which is not coated with a gate electrode, is coated with an insulating film to prevent silicidation.

Referring now to the accompanying drawings, a semiconductor device and a method for fabricating the same according to the present invention will be described below.

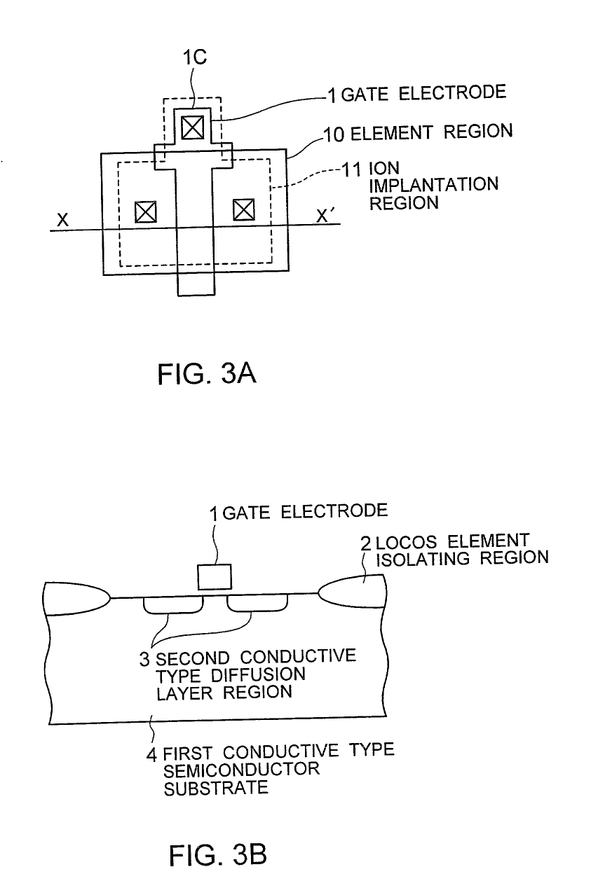

FIGS. 3A and 3B are plan and sectional views showing the construction of the first preferred embodiment of a semiconductor device according to the present invention. FIG. 3B is a sectional view taken along line X-X′ of FIG. 3A.

The first preferred embodiment of a semiconductor device according to the present invention comprises: an element isolating region 2, formed in the surface portion of a first conductive type semiconductor substrate 4 by the LOCOS method, for separating an element region 10; a gate electrode 1 crossing a central portion above the semiconductor substrate 2 in the element region 10 separated by the element isolating region 2, the gate electrode 1 having a contact portion 1C for connecting to another wiring layer, which is arranged at one end outside of the element region 10, and the gate electrode 1 having a shape which covers a boundary portion between the element region 10, which is arranged between the contact portion 1C and an interior of the element region 10, and the element isolating region 2, over a length exceeding a gate length in the central portion of the element region 10; an ion implantation region 11 for forming a diffusion layer, whose most part is included in the element region 10, and one part protrudes from the most part to include the contact portion 1C of the gate electrode, the ion implantation region 11 being arranged to avoid the boundary portion; and second conductive type diffusion layer regions 3 which are each formed in the surface portion of the semiconductor substrate 4 in regions included in one and the other of the element region 10 divided by the gate electrode 1 into substantially halves.

In the first preferred embodiment of a semiconductor device and a method for fabricating the same according to the present invention, the shape of the gate electrode 1 covering the boundary portion between the element region 10, which is arranged between the contact portion 1C and an interior of the element region 10, and the element isolating region 2, over a length exceeding a gate length is utilized so that the most part of the ion implantation region 11 used for forming the second conductive type diffusion layer region 3 is smaller than the element region 10 so as to be included in the element region 10 and so as to include the one end portion of the gate electrode 1 having the contact portion 1C while avoiding the exposure portion of the boundary portion between the element region 10 and the element isolating region 2.

That is, the first preferred embodiment of a method for fabricating a semiconductor device according to the present invention is carried out as follows. Referring to FIGS. 3A and 3B, this method will be described below.

First, an element isolating region 2 for separating an element region 10 is formed in the surface portion of a first conductive type semiconductor substrate 3 by the LOCOS method.

After forming the element isolating region 2, a gate electrode 1 is formed crossing a central portion above the semiconductor substrate 2 in the element region 10 separated by the element isolating region 2, the gate electrode 1 having a contact portion 1C for connecting to another wiring layer, which is arranged at one end outside of the element region 10, and the gate electrode 1 having a shape which covers a boundary portion between the element region 10, which is arranged between the contact portion 1C and an interior of the element region 10, and the element isolating region 2, over a length exceeding a gate length in the central portion of the element region 10.

After forming the gate electrode 1, ions are implanted into an ion implantation region 11 for forming a diffusion layer, whose most part is included in the element region 10, and one part protrudes from the most part to include the contact portion 1C of the gate electrode, the ion implantation region 11 being arranged to avoid the boundary portion, to form second conductive type diffusion layer regions 3 in the surface portion of the semiconductor substrate 4 in regions, which are included in one and the other of the element region 10 divided by the gate electrode 1 into substantially halves, to complete the first preferred embodiment of a semiconductor device according to the present invention which is shown in FIGS. 3A and 3B.

With the above described construction, the first preferred embodiment of a semiconductor device and a method for fabricating the same according to the present invention can carrying out the impurity doping into the gate electrode 1 simultaneously with the ion implantation for forming the source and drain diffusion layers 3 while suppressing the increase of the parasitic resistance from the contact portion 1C of the gate electrode 1 to a portion above the channel region, and can prevent the junction withstand voltage from lowering in the boundary portion between the element region 10 and the element isolating region 2 by avoiding the high-concentration ion implantation into the boundary portion.

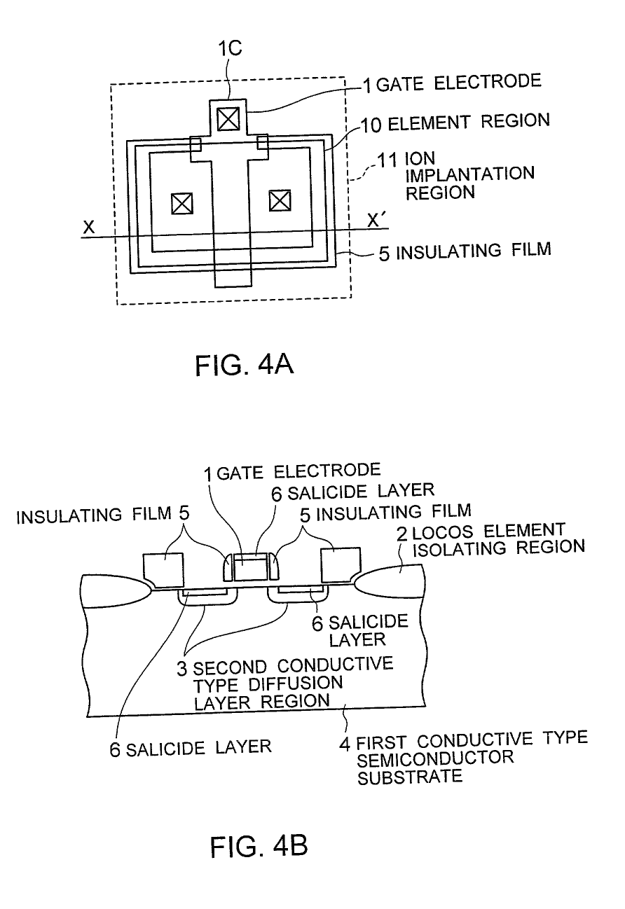

FIGS. 4A and 4B are plan and sectional views showing the construction of the second preferred embodiment of a semiconductor device according to the present invention. FIG. 4B is a sectional view taken along line X-X′ of FIG. 4A.

The second preferred embodiment of a semiconductor device according to the present invention comprises: an element isolating region 2, formed in the surface portion of a first conductive type semiconductor substrate 4 by the LOCOS method, for separating an element region 10; a gate electrode 1 crossing a central portion above the semiconductor substrate 2 in the element region 10 separated by the element isolating region 2, the gate electrode 1 having a contact portion 1C for connecting to another wiring layer, which is arranged at one end outside of the element region 10, and the gate electrode 1 having a shape which covers a boundary portion between the element region 10, which is arranged between the contact portion 1C and an interior of the element region 10, and the element isolating region 2, over a length exceeding a gate length in the central portion of the element region 10; an insulating film 5 which covers the boundary portion between the element region 10 and the element isolating region 2 as a frame shape except for a portion which the gate electrode 1 is formed; an ion implantation region 11 for forming a diffusion layer, which is arranged in a range including all of the gate electrode 1C and the insulating film 5; second conductive type diffusion layer regions 3 each formed in the surface portion of the semiconductor substrate 4 in regions included in one and the other of the element region 10 which is divided by the gate electrode 1 into substantially halves and which is surrounded by the insulating layer 5; and a salicide layer 6 which is formed on the top face of the gate electrode 1 and in the surface portion of the second conductive type diffusion layer regions 3.

In the second preferred embodiment of a semiconductor device and a method for fabricating the same according to the present invention, in order to eliminate the problem in that the diffusion layer region 3 is electrically connected to the outside of the element region 10 to produce a leak current if a portion of the element region 10 into which high density ions are not implanted, i.e., the peripheral portion of the element region 10, is silicidated when the salicide process is introduced, the boundary portion between the element region 10 and the element isolating region 2 is coated with the gate electrode 1 and the insulating film 5 to prevent the silicidation before the salicide process. The reason why the gate electrode 1 has a shape which covers the boundary portion between the element region 10, which is arranged between the contact portion 1C and an interior of the element region 10, and the element isolating region 2, over a length exceeding a gate length in the central portion of the element region 10 is that the gate electrode 1 is silicidated even on the boundary portion over a sufficient gate length. The silicidation in the salicide process is carried out by depositing a thin film of a metal, such as titanium, cobalt or nickel, on the whole surface of the element region 10 after forming the insulating film 5 and heat-treating the thin film.

That is, the second preferred embodiment of a method for fabricating a semiconductor device according to the present invention is carried out as follows. Referring to FIGS. 4A and 4B, this method will be described below.

First, an element isolating region 2 for separating an element region 10 is formed in the surface portion of a first conductive type semiconductor substrate 4 by the LOCOS method.

After forming the element isolating region 2, a gate electrode 1 is formed crossing a central portion above the semiconductor substrate 2 in the element region 10 separated by the element isolating region 2, the gate electrode 1 having a contact portion 1C for connecting to another wiring layer, which is arranged at one end outside of the element region 10, and the gate electrode 1 having a shape which covers a boundary portion between the element region 10, which is arranged between the contact portion 1C and an interior of the element region 10, and the element isolating region 2, over a length exceeding a gate length in the central portion of the element region 10.

After forming the gate electrode 1, an insulating film 5, which covers the boundary portion between the element region 10 and the element isolating region 2 as a frame shape except for a portion which the gate electrode 1 is formed, is formed.

After forming the insulating film 5, ions are implanted into an ion implantation region 11 for forming a diffusion layer, which is arranged in a range including all of the gate electrode 1 and the insulating film 5, to form second conductive type diffusion layer regions 3 in the surface portion of the semiconductor substrate 4 in regions included in one and the other of the element region 10 which is divided by the gate electrode 1 into substantially halves and which is surrounded by the insulating layer 5.

After forming the second conductive type diffusion layer region 3, a metal film is deposited on the whole surface of the element region 10 to be heat-treated to form a salicide layer 6 on the top face of the gate electrode 1 and in the surface portion of the second conductive type diffusion layer region 3, to form the second preferred embodiment of a semiconductor device according to the present invention which is shown in FIGS. 4A and 4B.

With the above described construction, the second preferred embodiment of a semiconductor device and a method for fabricating the same according to the present invention can realize a high junction withstand voltage even if the salicide process is introduced. Furthermore, if the insulating film 5 in the second preferred embodiment of a semiconductor device and a method for fabricating the same according to the present invention is formed by utilizing a gate-side wall forming insulating film for the salicide process, the process can be simplified, and the number of steps can be substantially equal to that in the conventional methods.

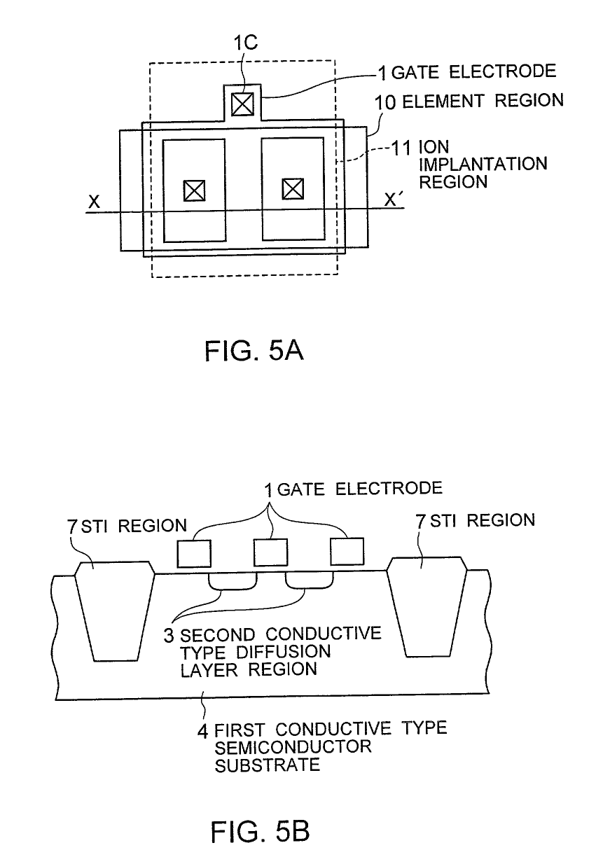

FIGS. 5A and 5B are plan and sectional views showing the construction of the third preferred embodiment of a semiconductor device according to the present invention. FIG. 5B is a sectional view taken along line X-X′ of FIG. 5A.

The third preferred embodiment of a semiconductor device according to the present invention comprises: an STI region 7, formed so as to extend from the surface portion of a first conductive type semiconductor substrate 4 to a predetermined depth, for separating an element region 10; a gate electrode 1 which is formed to have a central crossing portion crossing a central portion above the semiconductor substrate 4 in the element region 10 separated by the STI region 7, a frame portion covering a pair of two facing sides of the boundary portion between the STI region 7 and the element region 10 and a inside portion of the other two sides of the boundary portion except for the corner portions of the boundary portion, and two openings surrounded by the central crossing portion and the frame portion; an ion implantation region 11 for forming a diffusion layer, wherein a pair of facing boundary lines are arranged on the frame portion of the gate electrode 1 covering the inside portion of the other two sides of the boundary portion between the STI region 7 and the element region 10, and wherein the other pair of facing boundary lines are arranged outside of the gate electrode 1 and the element region 10; and second conductive type diffusion layer regions 3 each formed in the surface portion of the semiconductor substrate 4 in the two opening regions of the gate electrode 1, respectively.

In the third preferred embodiment of a semiconductor device and a method for fabricating the same according to the present invention, the pair of facing boundary lines of the diffusion layer forming ion implantation region 11 used for forming the second conductive type diffusion layer region 3 are set so as to be arranged on the frame portion of the gate electrode 1 covering the inside portion of the other two sides of the boundary portion between the STI region 7 and the element region 10, and the other pair of facing boundary lines of the diffusion layer forming ion implantation region 11 are set so as to be arranged outside of the gate electrode 1 and the element region 10. Therefore, it is not required to form the gate electrode on the corner portion of the boundary portion between the STI region 7 and the element region 10. In addition, high density ions are not implanted into the boundary portion and vicinity thereof, and silicidation is not carried out on the boundary portion and vicinity thereof.

That is, the third preferred embodiment of a method for fabricating a semiconductor device according to the present invention is carried out as follows. Referring to FIGS. 5A and 5B, this method will be described below.

First, an STI region 7 for separating an element region 10 is formed so as to extend from the surface portion of a first conductive type semiconductor substrate 4 to a predetermined depth.

After forming the STI region 7, a gate electrode 1 is formed to have a central crossing portion crossing a central portion above the semiconductor substrate 4 in the element region 10 separated by the STI region 7, a frame portion covering a pair of two facing sides of the boundary portion between the STI region 7 and the element region 10 and a inside portion of the other two sides of the boundary portion except for the corner portions of the boundary portion, and two openings surrounded by the central crossing portion and the frame portion.

After forming the gate electrode 1, ions are implanted into an ion implantation region 11 for forming a diffusion layer, wherein a pair of facing boundary lines are arranged on the frame portion of the gate electrode 1 covering the inside portion of the other two sides of the boundary portion between the STI region 7 and the element region 10, and wherein the other pair of facing boundary lines are arranged outside of the gate electrode 1 and the element region 10, to form second conductive type diffusion layer regions 3 in the surface portion of the semiconductor substrate 4 in the two opening regions of the gate electrode 1, respectively, to complete the third preferred embodiment of a semiconductor device according to the present invention which is shown in FIGS. 5A and 5B.

With the above described construction, the third preferred embodiment of a semiconductor device and a method for fabricating the same according to the present invention can prevent a short circuit from being established between the gate electrode and the substrate in the boundary portion between the element region 10 and the STI region 7, particularly in the corner portion, even if the element isolating region is the STI region 7 formed by the STI method, so that the diffusion layer region 3 is not electrically connected to the boundary portion. Therefore, it is possible to realize a high junction withstand voltage. Furthermore, with the above described construction, in the third preferred embodiment of a semiconductor device and a method for fabricating the same according to the present invention, the doping of impurities into the gate electrode 1 and the diffusion layer region 3 can be simultaneously carried out at the same step.

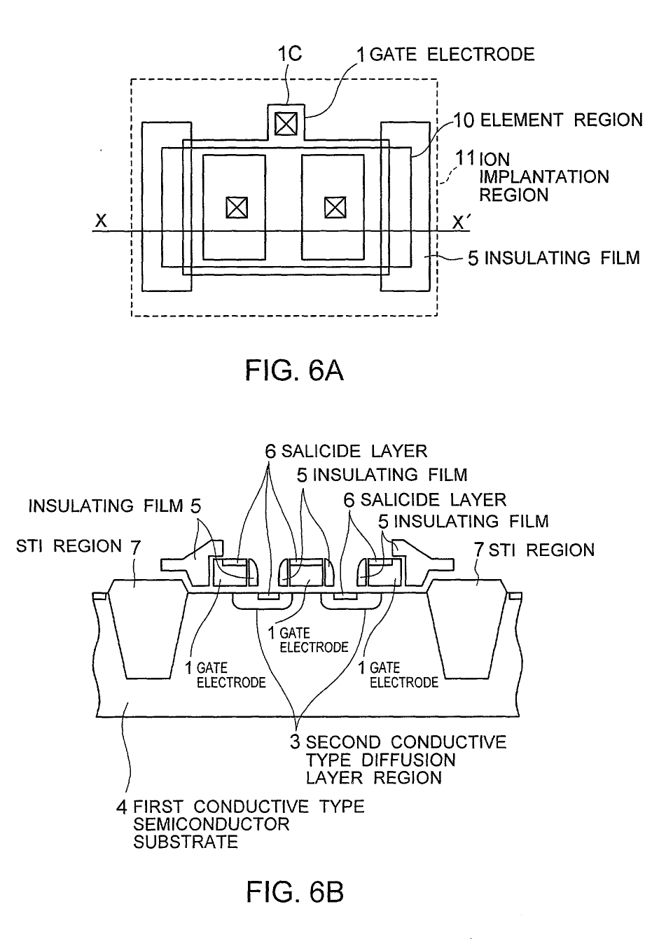

FIGS. 6A and 6B are plan and sectional views showing the construction of the fourth preferred embodiment of a semiconductor device according to the present invention. FIG. 6B is a sectional view taken along line X-X′ of FIG. 6A.

The fourth preferred embodiment of a semiconductor device according to the present invention comprises: an STI region 7, formed so as to extend from the surface portion of a first conductive type semiconductor substrate 4 to a predetermined depth, for separating an element region 10; a gate electrode 1 which is formed to have a central crossing portion crossing a central portion above the semiconductor substrate 4 in the element region 10 separated by the STI region 7, a frame portion covering a pair of two facing sides of the boundary portion between the STI region 7 and the element region 10 and a inside portion of the other two sides of the boundary portion except for the corner portions of the boundary portion, and two openings surrounded by the central crossing portion and the frame portion; an insulating film 5 formed so as to cover the element region 10 outside of the frame portion of the gate electrode land the boundary portion; an ion implantation region 11 for forming a diffusion layer, formed in a range including all of the gate electrode 1 and the insulating film 5; second conductive type diffusion layer regions 3 each formed in the surface portion of the semiconductor substrate 4 in the two opening regions of the gate electrode 1; and a salicide layer 6 formed on the exposed top face of the gate electrode 1 and in the surface portion of the second conductive type diffusion layer region 3.

In the fourth preferred embodiment of a semiconductor device and a method for fabricating the same according to the present invention, the insulating film 5 covering the element region 10 outside of the frame portion of the gate electrode 1 and the boundary portion is formed before the high-density ion implantation and the salicide process so that it is not required to carry out the fine adjustment in the range of the diffusion layer forming ion implantation region 11 unlike the above described third preferred embodiment. The silicidation by the salicide process is carried out by depositing a thin film of a metal, such as titanium, cobalt or nickel, on the whole surface of the element region 10, on which the insulating film 5 has been formed, and heat-treating the thin film.

Therefore, it is not required to form the gate electrode on the corner portion of the boundary portion between the STI region 7 and the element region 10. In addition, high density ions are not implanted into the boundary portion and vicinity thereof, and silicidation is not carried out on the boundary portion and vicinity thereof.

With the above described construction, the fourth preferred embodiment of a semiconductor device and a method for fabricating the same according to the present invention can prevent a short circuit from being established between the gate electrode and the substrate in the boundary portion between the element region 10 and the STI region 7, particularly in the corner portion, even if the element isolating region is the STI region 7 formed by the STI method, so that the diffusion layer region 3 is not electrically connected to the boundary portion. Therefore, it is possible to realize a high junction withstand voltage.

With the above described construction, in the fourth preferred embodiment of a semiconductor device and a method for fabricating the same according to the present invention, the doping of impurities into the gate electrode 1 and the diffusion layer region 3 can be simultaneously carried out at the same step. If the insulating film 5 is formed by utilizing a gate-side wall forming insulating film for the salicide process, the process can be simplified, and the number of steps can be substantially equal to that in the conventional methods. Furthermore, if a gate-side wall forming insulating film is utilized for coating with an insulating film in order to utilize a non-silicidated diffusion layer or the like as a resistive element although there is no intimate relationship between this and the principle of the present invention, the process can be simplified, and the number of steps can be substantially equal to that in the conventional methods.

Referring to the accompanying drawings, steps of a method for fabricating the fourth preferred embodiment of a semiconductor device according to the present invention will be described below in detail since the steps are slightly more complicated than those of the other preferred embodiments of a semiconductor device according to the present invention.

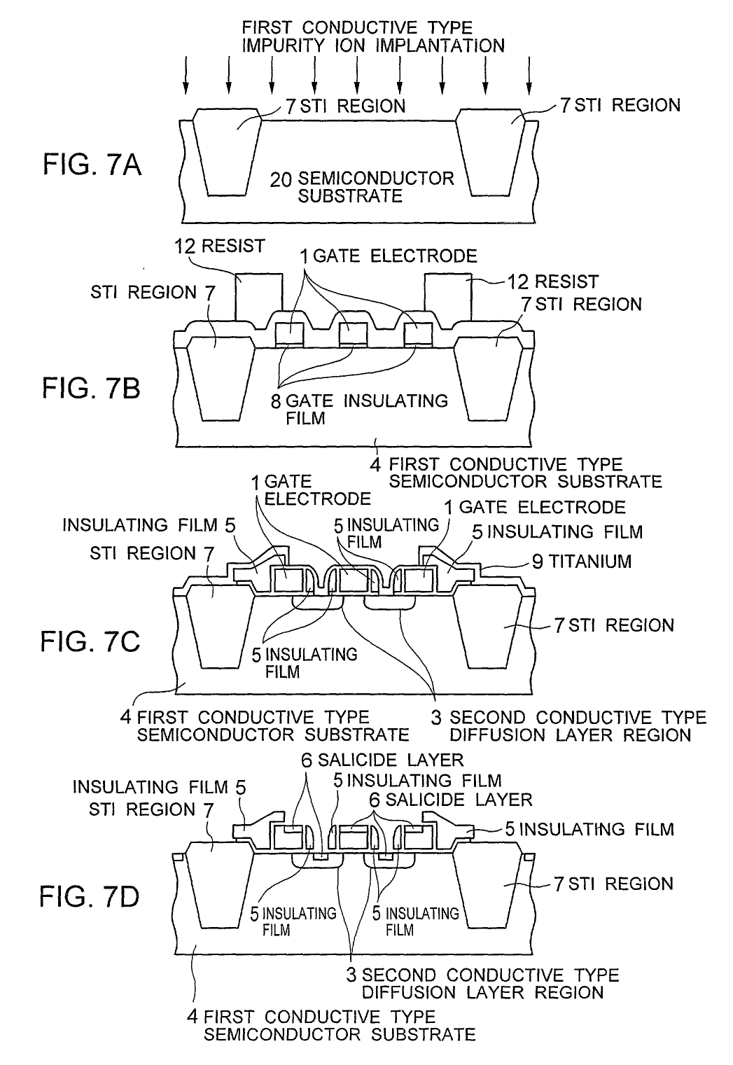

FIGS. 7A, 7B, 7C and 7D are sectional views showing principal steps of a method for fabricating the fourth preferred embodiment of a semiconductor device according to the present invention.

First, as shown in FIG. 7A, after an STI region 7 serving as an element isolating region having a depth of about 0.3 μm is formed by the STI method in the surface portion of a p-type semiconductor substrate 20 having an impurity density of 5×10¹⁴ cm⁻³ in the vicinity of the surface, boron serving as a p-type impurity is implanted at an acceleration energy of 30 kev so as to have a density of 1×10^{13 cm}⁻³, to form a p-type well. That is, the p-type well having a predetermined depth from the surface of the semiconductor substrate 20 is formed, and it will be hereinafter referred to as a first conductive type semiconductor substrate 4.

Thereafter, a gate insulating film 8 having a thickness of about 17 nm is formed on the surface of the semiconductor substrate 4, and a gate electrode of a non-doped polysilicon having a thickness of about 200 nm is formed on the gate insulating film 8. Then, the gate insulating film 8 and the gate electrode 1 are processed to have the above described shape. That is, the gate insulating film 8 and the gate electrode 1 are processed to have a central crossing portion crossing a central portion above the semiconductor substrate 4 in the element region 10 separated by the STI region 7, a frame portion covering a pair of two facing sides of the boundary portion between the STI region 7 and the element region 10 and a inside portion of the other two sides of the boundary portion except for the corner portions of the boundary portion, and two openings surrounded by the central crossing portion and the frame portion.

After the gate insulating film 8 and the gate electrode 1 are processed, as shown in FIG. 7B, the surface of the substrate is oxidized by a thickness of about 10 nm, and a silicon nitride film (Si₃N₄) having a thickness of about 100 nm is deposited on the whole surface to form an insulating film 5. Then, a resist 12 is formed on a portion in which the insulating film 5 should be left, i.e., a portion covering the element region 10 and the boundary portion outside of the frame portion of the gate electrode 1.

After forming the resist 12, the insulating film 5 is selectively etched, and arsenic ions are implanted at an acceleration energy of 45 keV so as to have a density of 3×10¹⁵ cm⁻³, to form a second conductive type diffusion layer region 3. Then, as shown in FIG. 7C, titanium 9 is deposited on the whole surface by sputtering so as to have a thickness of about 35 nm.

After depositing titanium, a salicide process is carried out by a heat treatment at a temperature of about 850° C. to silicidate portions of the top portion of the gate electrode 1 and the surface portion of the diffusion layer region 3 contacting the titanium 9. Thereafter, unreacted titanium is removed with an acidic solution, so that the fourth preferred embodiment of a semiconductor device according to the present invention which is the same as that shown in FIG. 6B is completed as shown in FIG. 7D.

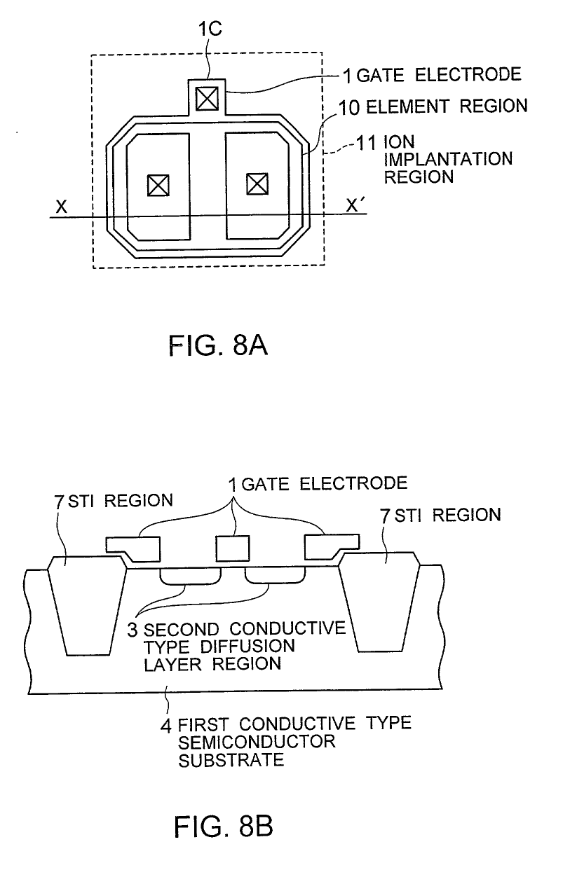

FIGS. 8A and 8B are plan and sectional views showing the construction of the fifth preferred embodiment of a semiconductor device according to the present invention. FIG. 8B is a sectional view taken along line X-X′ of FIG. 8A.

The fifth preferred embodiment of a semiconductor device according to the present invention comprises: an STI region 7, formed so as to extend from the surface portion of a first conductive type semiconductor substrate 4 to a predetermined depth, for separating a substantially rectangular element region 10, each corner portion of which has two corners having an internal angle of about 135°; a gate electrode 1 which is formed to have a central crossing portion crossing a central portion above the semiconductor substrate 4 in the element region 10 separated by the STI region 7, a frame portion covering the boundary portion between the STI region 7 and the element region 10, and two openings surrounded by the central crossing portion and the frame portion; an ion implantation region 11 for forming a diffusion layer, formed in a range including all of the gate electrode 1; and second conductive type diffusion layer regions 3 formed in the surface portion of the semiconductor substrate 4 in the two opening regions of the gate electrode 1, respectively.

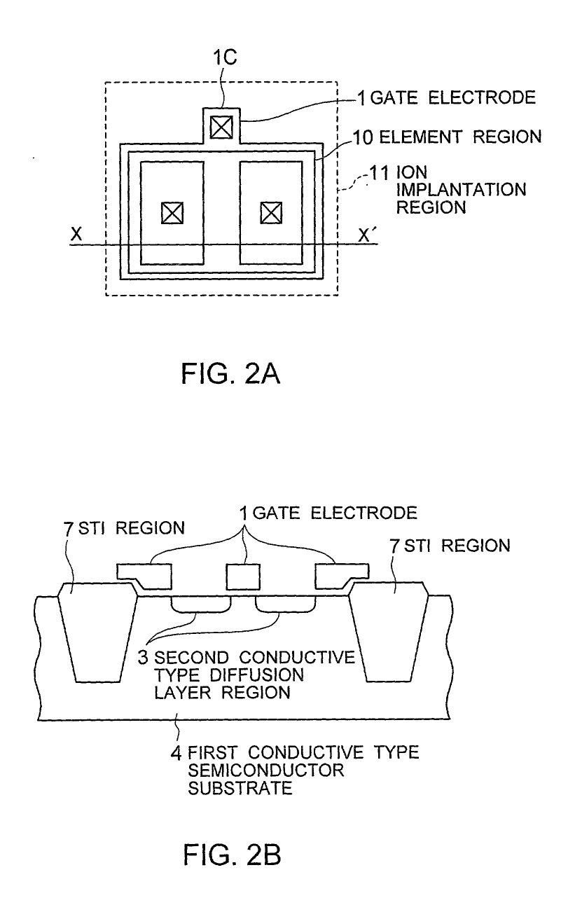

As described above, in the second conventional MOS transistor shown in FIGS. 2A and 2B, there is a problem in that a short circuit is easily established between the gate electrode, which covers the boundary portion between the element region 10 and the STI region 7, and the substrate in the right-angled corner portion of the boundary portion. It has been founded that this problem is often caused when the corner portions of the element region 10 are right-angled or acute-angled.

Therefore, in the fifth preferred embodiment of a semiconductor device and a method for fabricating the same according to the present invention, the shape of the element region 10 is a shape wherein each corner portion of a rectangle is removed at an angle of about 45°, i.e., a substantially rectangle, each corner portion of which has two angles having an internal angle of about 135°. In accordance with this, the shape of the frame portion of the gate electrode 1 is a shape which covers the boundary portion between the element region 10 and the STI region 7.

That is, the fifth preferred embodiment of a method for fabricating a semiconductor device according to the present invention is carried out as follows. Referring to FIGS. 8A and 8B, this method will be described below.

First, an STI region 7 for separating a substantially rectangular element region 10, each corner portion of which has an arc-shaped or a plurality of obtuse corners, is formed so as to extend from the surface portion of a first conductive type semiconductor substrate 4 to a predetermined depth.

After forming the STI region 7, a gate electrode 1 is formed to have a central crossing portion crossing a central portion above the semiconductor substrate 4 in the element region 10 separated by the STI region 7, a frame portion covering the boundary portion between the STI region 7 and the element region 10, and two openings surrounded by the central crossing portion and the frame portion.

After forming the gate electrode 1, ions are implanted into an ion implantation region 11 for forming diffusion layer in a range including all of the gate electrode 1 to form second conductive type diffusion layer regions 3 in the surface portion of the semiconductor substrate 4 in the two opening regions of the gate electrode 1, respectively, to complete the fifth preferred embodiment of a semiconductor device according to the present invention which is shown in FIGS. 8A and 8B.

As described above, in the fifth preferred embodiment of a semiconductor device and a method for fabricating the same according to the present invention, a right-angled or acute-angled portion is removed from the peripheral portion of the element region 10. Therefore, it is possible to prevent a short circuit from being established between the gate electrode, which covers the boundary portion between the element region 10 and the STI region 7, and the substrate in the corner portion of the boundary portion, so that it is possible to realize a high junction withstand voltage.

In this preferred embodiment, as a simplest construction, the shape of the element region 10 is a substantially rectangle, each corner portion of which has two corners having an internal angle of about 135°. However, the shape of each corner portion of the element region 10 is preferably a polygonal having a greater internal angle or an arch having a greater radius.

As described above, according to a semiconductor device and a method for fabricating the same according to the present invention, the shape of the gate electrode, the shape or range of the diffusion layer forming ion implantation region, or the peripheral shape of the element region is improved, or a part of the element region is coated with the insulating film before ion implantation, so that it is possible to realize a semiconductor device having a high junction withstand voltage.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A semiconductor device comprising:
an element isolating region, formed in the surface portion of a first conductive type semiconductor substrate, for separating an element region;
a gate electrode crossing a central portion above said semiconductor substrate in said element region separated by said element isolating region, said gate electrode having a contact portion for connecting to another wiring layer, which is arranged at one end outside of said element region, and said gate electrode having a shape which covers a boundary portion between said element region, which is arranged between said contact portion and an interior of said element region, and said element isolating region, over a length exceeding a gate length in the central portion of said element region;
an ion implantation region for forming a diffusion layer, whose most part is included in said element region, and one part protrudes from said most part to include said contact portion of said gate electrode, said ion implantation region being arranged to avoid said boundary portion; and
second conductive type diffusion layer regions which are each formed in the surface portion of said semiconductor substrate in regions included in one and the other of said element region divided by said gate electrode into substantially halves.

2. A semiconductor device comprising:
an element isolating region, formed in the surface portion of a first conductive type semiconductor substrate, for separating an element region;
a gate electrode crossing a central portion above said semiconductor substrate in said element region separated by said element isolating region, said gate electrode having a contact portion for connecting to another wiring layer, which is arranged at one end outside of said element region, and said gate electrode having a shape which covers a boundary portion between said element region, which is arranged between said contact portion and an interior of said element region, and said element isolating region, over a length exceeding a gate length in the central portion of said element region;
an insulating film which covers the boundary portion between said element region and said element isolating region as a frame shape except for a portion which said gate electrode is formed;
an ion implantation region for forming a diffusion layer, which is arranged in a range including all of said gate electrode and said insulating film;
second conductive type diffusion layer regions each formed in the surface portion of said semiconductor substrate in regions included in one and the other of said element region which is divided by said gate electrode into substantially halves and which is surrounded by said insulating layer; and
a salicide layer which is formed on the top face of said gate electrode and in the surface portion of said second conductive type diffusion layer regions.

3. A semiconductor device comprising:
an STI (shallow trench isolation) region, formed so as to extend from the surface portion of a first conductive type semiconductor substrate to a predetermined depth, for separating an element region;
a gate electrode which is formed to have a central crossing portion crossing a central portion above said semiconductor substrate in said element region separated by said STI region, a frame portion covering a pair of two facing sides of the boundary portion between said STI region and said element region and a inside portion of the other two sides of said boundary portion except for the corner portions of said boundary portion, and two openings surrounded by said central crossing portion and said frame portion;
an ion implantation region for forming a diffusion layer, wherein a pair of facing boundary lines are arranged on said frame portion of said gate electrode covering the inside portion of the other two sides of the boundary portion between said STI region and said element region, and wherein the other pair of facing boundary lines are arranged outside of said gate electrode and said element region; and
second conductive type diffusion layer regions each formed in the surface portion of said semiconductor substrate in said two opening regions of said gate electrode, respectively.

4. A semiconductor device comprising:
an STI region, formed so as to extend from the surface portion of a first conductive type semiconductor substrate to a predetermined depth, for separating an element region;
a gate electrode which is formed to have a central crossing portion crossing a central portion above said semiconductor substrate in said element region separated by said STI region, a frame portion covering a pair of two facing sides of the boundary portion between said STI region and said element region and a inside portion of the other two sides of said boundary portion except for the corner portions of said boundary portion, and two openings surrounded by said central crossing portion and said frame portion;
an insulating film formed so as to cover said element region outside of said frame portion of said gate electrode and said boundary portion;
an ion implantation region for forming a diffusion layer, formed in a range including all of said gate electrode and said insulating film;
second conductive type diffusion layer regions each formed in the surface portion of said semiconductor substrate in said two opening regions of said gate electrode; and
a salicide layer formed on the exposed top face of said gate electrode and in the surface portion of said second conductive type diffusion layer region.

5. A semiconductor device comprising:
an STI region, formed so as to extend from the surface portion of a first conductive type semiconductor substrate to a predetermined depth, for separating a substantially rectangular element region, each corner portion of which has an arc shape or a plurality of corners of an acute angle;
a gate electrode which is formed to have a central crossing portion crossing a central portion above said semiconductor substrate in said element region separated by said STI region, a frame portion covering the boundary portion between said STI region and said element region, and two openings surrounded by said central crossing portion and said frame portion;
an ion implantation region for forming diffusion layer, formed in a range including all of said gate electrode; and
second conductive type diffusion layer regions formed in the surface portion of said semiconductor substrate in said two opening regions of said gate electrode, respectively.

6. A method for fabricating a semiconductor device comprising the steps of:
forming an element isolating region for separating an element region in the surface portion of a first conductive type semiconductor substrate;
forming a gate electrode crossing a central portion above said semiconductor substrate in said element region separated by said element isolating region, said gate electrode having a contact portion for connecting to another wiring layer, which is arranged at one end outside of said element region, and said gate electrode having a shape which covers a boundary portion between said element region, which is arranged between said contact portion and an interior of said element region, and said element isolating region, over a length exceeding a gate length in the central portion of said element region; and
implanting ions into an ion implantation region for forming a diffusion layer, whose most part is included in said element region, and one part protrudes from said most part to include said contact portion of said gate electrode, said ion implantation region being arranged to avoid said boundary portion, to form second conductive type diffusion layer regions in the surface portion of said semiconductor substrate in regions, which are included in one and the other of said element region divided by said gate electrode into substantially halves.

7. A method for fabricating a semiconductor device comprising the steps of:
forming an element isolating region for separating an element region in the surface portion of a first conductive type semiconductor substrate;
forming a gate electrode crossing a central portion above said semiconductor substrate in said element region separated by said element isolating region, said gate electrode having a contact portion for connecting to another wiring layer, which is arranged at one end outside of said element region, and said gate electrode having a shape which covers a boundary portion between said element region, which is arranged between said contact portion and an interior of said element region, and said element isolating region, over a length exceeding a gate length in the central portion of said element region;
forming a gate electrode so as to have a shape which crosses a central portion above said semiconductor substrate in said element region separated by said element isolating region, which has a contact portion provided outside of said element region at one end thereof to be connected to another wiring layer, and which covers the boundary portion between said element region and said element isolating region, which is arranged between said contact portion and the interior of said element region, over a length exceeding a gate length in the central portion of said element region;
forming an insulating film which covers the boundary portion between said element region and said element isolating region as a frame shape except for a portion which said gate electrode is formed;
implanting ions into a diffusion layer forming ion implantation region which is arranged in a range including all of said gate electrode and said insulating film, to each form second conductive type diffusion layer regions in the surface portion of said semiconductor substrate in regions included in one and the other of said element region which is divided by said gate electrode into substantially halves and which is surrounded by said insulating layer; and
depositing and heat-treating a metal film on the whole surface of said element region to form a salicide layer on the top face of said gate electrode and in the surface portion of said second conductive type diffusion layer regions.

8. A method for fabricating a semiconductor device comprising the steps of:
forming an STI region for separating an element region so as to extend from the surface portion of a first conductive type semiconductor substrate to a predetermined depth;
forming a gate electrode to have a central crossing portion crossing a central portion above said semiconductor substrate in said element region separated by said STI region, a frame portion covering a pair of two facing sides of the boundary portion between said STI region and said element region and a inside portion of the other two sides of said boundary portion except for the corner portions of said boundary portion, and two openings surrounded by said central crossing portion and said frame portion; and
implanting ions into a diffusion layer forming ion implantation region wherein a pair of facing boundary lines are arranged on said frame portion of said gate electrode covering the inside portion of the other two sides of the boundary portion between said STI region and said element region and wherein the other pair of facing boundary lines are arranged outside of said gate electrode and said element region, to form second conductive type diffusion layer regions in the surface portion of said semiconductor substrate in said two opening regions of said gate electrode, respectively.

9. A method for fabricating a semiconductor device comprising the steps of:
forming an STI region for separating an element region so as to extend from the surface portion of a first conductive type semiconductor substrate to a predetermined depth;
forming a gate electrode to have a central crossing portion crossing a central portion above said semiconductor substrate in said element region separated by said STI region, a frame portion covering a pair of two facing sides of the boundary portion between said STI region and said element region and a inside portion of the other two sides of said boundary portion except for the corner portions of said boundary portion, and two openings surrounded by said central crossing portion and said frame portion;
forming an insulating film covering said element region and said boundary portion outside of said frame portion of said gate electrode;
implanting ions into a diffusion layer forming ion implantation region, which includes all of said gate electrode and said insulating film, to form second conductive type diffusion layer regions in the surface portion of said semiconductor substrate in said two opening regions of said gate electrode, respectively; and
depositing and heat-treating a metal film on the whole surface of said element region to form a salicide layer on the exposed top face of said gate electrode and in the surface portion of said second conductive type diffusion layer regions.

10. A method for fabricating a semiconductor device comprising the steps of:
forming an STI region for separating a substantially rectangular element region, each corner portion of which has an arc-shaped or a plurality of obtuse corners, so as to extend from the surface portion of a first conductive type semiconductor substrate to a predetermined depth;
forming a gate electrode to have a central crossing portion crossing a central portion above said semiconductor substrate in said element region separated by said STI region, a frame portion covering the boundary portion between said STI region and said element region, and two openings surrounded by said central crossing portion and said frame portion; and
implanting ions into a diffusion layer forming ion implantation region in a range including all of said gate electrode to form second conductive type diffusion layer regions in the surface portion of said semiconductor substrate in said two opening regions of said gate electrode, respectively.
